(19) United States
(12) Patent Application Publication
(10) Pub. No.: US 2008/0003082 A1
(43) Pub. Date: Jan. 3, 2008

(54) Holding apparatus for substrate cassette and storage method for the same

(75) Inventors: Hideto Motoshima, Kawasaki (JP); Yoshihide Iio, Kawasaki (JP); Masami Yamashita, Kawasaki (JP)

Correspondence Address: YOUNG & THOMPSON, 745 SOUTH 23RD STREET, 2ND FLOOR, ARLINGTON, VA, 22202, US

(73) Assignee: NEC LCD TECHNOLOGIES, LTD., Kawasaki (JP)

(21) Appl. No.: 11/819,237

(22) Filed: Jun. 26, 2007

(30) Foreign Application Priority Data
Jun. 29, 2006 (JP) 2006-178931

(51) Int. Cl. H01L 21/677

(52) U.S. Cl. 414/217.1

(57) ABSTRACT

A holding apparatus for a substrate cassette include a support base for holding the cassette with substrates. A tilting device is fixed to the support base for allowing the support base to rotate about a horizontal axis from a horizontal position, wherein top surfaces of the substrates are arranged upwardly, to an over vertical position, wherein the top surfaces of the substrates are arranged downwardly, by rotating the support base over 90 degrees. A storage method for a substrate cassette includes steps of storing a substrate in the cassette for substrates almost horizontally, fixing a cassette on a support base, and rotating the support base around a rotary shaft so that the substrate may rotate to the angle beyond 90 degrees.

This application is based upon and claims the benefit of priority from Japanese patent application No. 2006-178931, filed on Jun. 29, 2006, the disclosure of which is incorporated herein in its entirety by reference.

### BACKGROUND OF THE INVENTION

1. Field of the Invention

The present invention relates to a holding apparatus for a substrate cassette and a storage method for the substrate cassette, especially to a holding apparatus for the cassette to reduce dust adhesion to surface of the substrates and a storage method for the cassette.

2. Description of the Related Art

Flat panel display devices such as a liquid crystal display (LCD) device and a plasma display device generally use a pair of large-sized glass substrates. In case of the LCD device, for example, a liquid crystal material is sandwiched between a pair of glass substrate's such as an array substrate and a color-filter substrate to provide an LCD panel. In a production line of the LCD panel, a cassette for storing a plurality of glass substrates is used for storage or transport of the substrates as a unit so as not decrease processing ability of the production line.

Generally, the substrates are subjected to any of various processing steps, such as film formation, etching and so on. The cassette receives the substrates therein to load or unload the substrates on or from processing equipment. That is, the cassette is used as a transferring device for the substrates received therein. In the cassette, the substrates are arranged in a stack-like configuration and each substrate is in a spaced and confronting relation with adjacent substrates so that processed top surfaces of the substrates are kept away from the processed bottom surfaces of adjacent substrates. Such a substrate cassette is illustrated in U.S. Pat. No. 5,890,598.

In an array processing step for the array substrates in which display elements such as pixel electrodes, thin-film transistors and circuit patterns are formed through several lithography processes, and various processing equipment needs to be cleaned periodically. Therefore, a waiting time or a storage period for the processed substrates stored in the cassette tends to increase.

During a long storage period, quality of the processed surfaces of the substrates may change. When change in quality of the processed surfaces occurs after the dust has adhered thereon, it is also confirmed that the removal ratio of the dust itself decreases. Therefore, it is important to avoid the adhesion of the dust on the processed surfaces of the substrates during the storage period of the cassette.

Generally, even if a glass substrate is being left in the clean room, dust adheres to the substrate in the following reason. That is, when film-forming and the pattern are formed on the surface of the glass substrate, the rear surface of the glass substrate touches a plate of a production unit. Dust on the plate may be transferred to the rear surface of the glass substrate at the time of this contact. As the result, the dust is carried with the glass substrates. When the glass substrate is stored in the cassette, dust may fall in a glass surface of substrate neighboring the underside of the substrate.

A cassette which holds it vertically by suspending and stores a glass substrate is considered to reduce the adhesion of dust on the substrate. However, when placed regularly, dust is considered to adhere on the coating and the pattern part of a glass substrate, so this is not a sufficient measure.

Referring to FIG. 9, in general, each processed substrate 1 is provided with film-forming patterns 2, such as pixel electrodes on one of main surface of a glass board 3. Such processed substrates are stored in a cassette 10 as shown in FIG. 10C.

This cassette 10 has a box-shaped structure as shown in FIGS. 10A to 10C. That is, the cassette 10 has a floor plate 11, a top plate 12, a plurality of side plates 13, and a stopper 14. The side plates 13 are provided with a plurality of supporting teeth or plates 16 which are arranged by a regular interval. Each outer edge section of the substrates 1 is supported by the supporting plates 16. When the substrates 1 are loaded in the cassette 10 through a loading aperture, the stopper 14 prevents the substrates 1 slipping out from the cassette 10 at the opposite side of the loading aperture.

Center teeth or plates 15 are projected from the stopper 14 to support the substrates 1. These center supports 15 are provided to prevent the bending of the substrates 1. The larger the size of the substrates 1 becomes, the larger the bending at central parts of the substrates becomes when the substrates 1 are loaded horizontally. In this case, contact between adjacent substrates 1 is prevented by the center support 15. The center supports 15 also prevent a crack in the substrates during conveying the cassette in swing movement.

Technologies relating to the substrate cassette are also proposed in, e.g., Japanese Patent Application Laid-Open No. 2003-152069 (a first related art), Japanese Patent Application Laid-Open No. Hei10 (1998)-18033 (a second related art), and Japanese Patent Application Laid-Open No. 2002-343846 (a third related art).

### SUMMARY OF THE INVENTION

Accordingly, therefore, the exemplary feature of the present invention is to provide a holding apparatus for a substrate cassette and a storage method for the substrate cassette which cannot make dust adhere to the processed surfaces of the substrates easily, even for a long storage period.

A holding apparatus for a substrate cassette according to exemplary aspect of the present invention include a support base for holding the cassette with substrates. A tilting device is fixed to the support base for allowing the support base to rotate about a horizontal axis from a horizontal position, wherein top surfaces of the substrates are arranged upwardly, to an over vertical position, wherein the top surfaces of the substrates are arranged downwardly, by rotating the support base over 90 degrees.

A storage method for a substrate according to an exemplary aspect of the present invention includes steps of storing substrates in a cassette horizontally, fixing the cassette on support bases, and rotating the support base around a rotary shaft to the angle which exceeds 90 degrees for the substrates.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

The above and other objects, features and advantages of the present invention will become more apparent from the following detailed description when taken in conjunction with the accompanying drawings wherein:

FIG. 1 is a perspective view illustrating a holding apparatus for a substrate cassette of the first exemplary embodiment of the present invention;

FIGS. 2A and 2B are a front view and a side view of a holding apparatus of FIG. 1, respectively;

FIG. 3 is a front view showing the state that rotated a holding apparatus of FIG. 1 beyond 90 degrees;

FIG. 4 is a front view showing the state of 180 degree rotation for the holding apparatus of FIG. 1;

FIG. 5 is a graph illustrating the dust adhesion situation on the substrate in the holding apparatus of the first exemplary embodiment;

FIG. 6 is a perspective view illustrating a holding apparatus for a substrate cassette of the second exemplary embodiment of the present invention;

FIG. 7 is a front view of a holding apparatus of FIG. 6;

FIG. 8 is a perspective view of the holding apparatus of FIG. 6 seen from the different direction;

FIG. 9 is a sectional view illustrating the structure of a general glass substrate;

FIG. 10A is a perspective view of a substrate cassette of the related art;

FIG. 10B is a front view of a substrate cassette of the related art; and

FIG. 10C is a front view of a substrate cassette of the related art of the state that glass substrates are stored.

### DETAILED DESCRIPTION OF THE EXEMPLARY EMBODIMENTS

Preferred embodiments of the present invention will now be described in detail in accordance with the accompanying drawings.

A holding apparatus for a substrate cassette according to an exemplary embodiment of the present invention includes a cassette for storing substrates, a support base for holding the cassette and a tilting device which is attached to the support base and rotates the support base around a rotary shaft over 90 degrees.

A storage method for a substrate cassette according to an exemplary embodiment of the present invention includes steps of storing a substrate in a cassette almost horizontally; fixing the cassette on a support base, and rotating the support base around a rotary shaft 90 degrees.

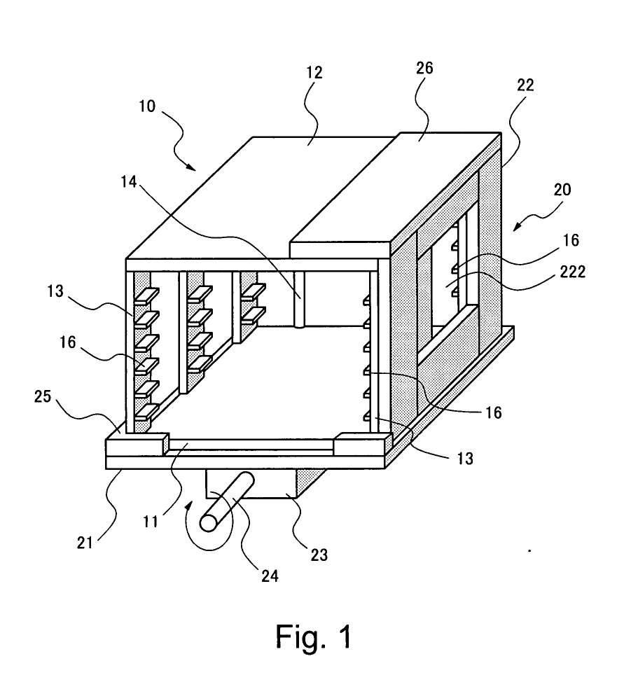

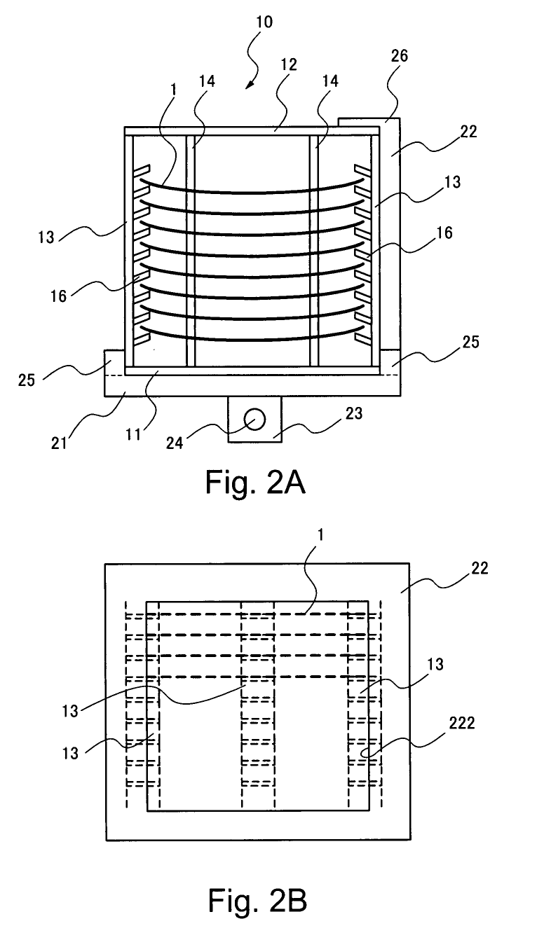

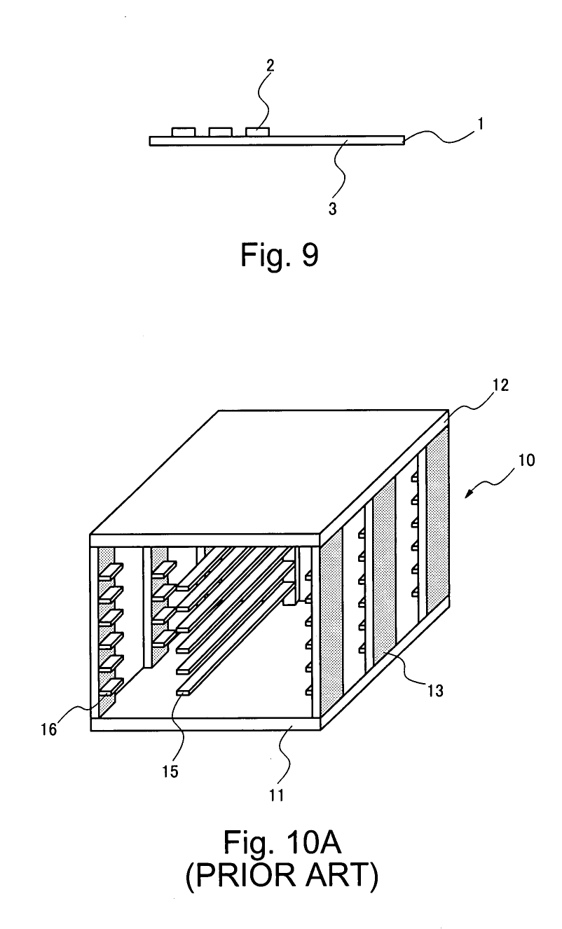

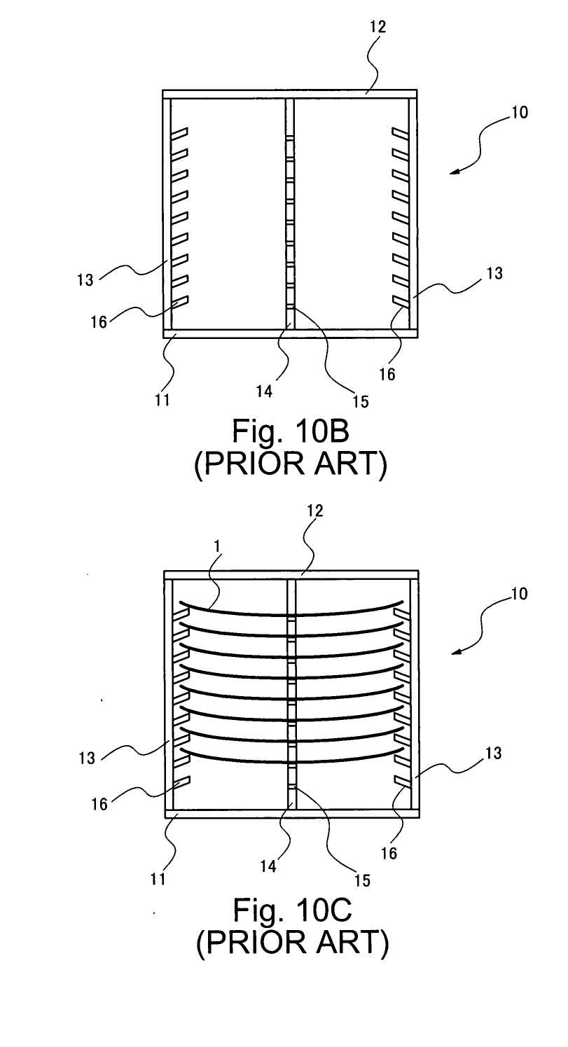

As shown in FIG. 1, a box-like cassette 10 used for this holding apparatus includes a floor plate 11, a top plate 12, a plurality of side plates 13 provided with teeth or supporting plates 16, and a pair of stoppers 14 at a rear side. The side plates 13 support the substrates 1 at side edges. The supporting plates 16 are provided on each inner surface of the side plates 13 with a regular interval. When the substrates 1 are loaded in the cassette 10 through a loading/unloading aperture thereof, the stopper 14 prevents the substrates 1 slipping out from the cassette 10 on the opposite side of the loading aperture. Each outer edge section of the substrates 1 stored in the cassette 10 is supported by the supporting plate 16. Needless to say, film-forming pattern 2 of FIG. 9 is formed on each top surface of these substrates 1 while the unprocessed bottom surface thereof has no such pattern.

As shown in FIG. 1, the holding apparatus 20 for the substrate cassette according to the first exemplary embodiment includes a first support base 21, a second support base 22, a tilting device 23 with a rotary shaft 24, first frame parts 25, and a second frame part 26. The first support base 21 mainly supports the floor plate 11 at initial stage. The second support base 22 supports a side of the cassette 10 secondarily at the initial stage. The second support base 22 has the structure like a frame, and has an opening 222 in order to visually recognize supporting condition of the substrates in the cassette 10. The tilting device 23 is attached to the base center of the first support base 21 and rotates support bases 21 and 22 around a rotary shaft 24. The rotary shaft 24 is arranged to have a horizontal axis extending to the substantially parallel direction of the insertion direction or loading direction of the substrates 1 to the cassette 10. Frame parts 25 and 26 are provided on the four corners so as to hold the cassette 10 with support bases 21 and 22. That is, the cassette 10 is fixed and held by the first support base 21, the second support base 22, the frame parts 25 and the frame part 26. Here, as shown in FIG. 1, the frame part 25 of the first support base 21 has a shape of letter “L”. The frame part 26 of the second support base 22 is a plate-shaped supporting member as shown in FIG. 1. Further, the support bases 21 and 22 are not needed to be a separate member, but an integrated one with a cross-sectional shape of letter “L”. In FIG. 1, the first support base 21 is placed to support the floor plate 11 of the cassette 10, and the second support base 22 is placed to support one of the side plates 13.

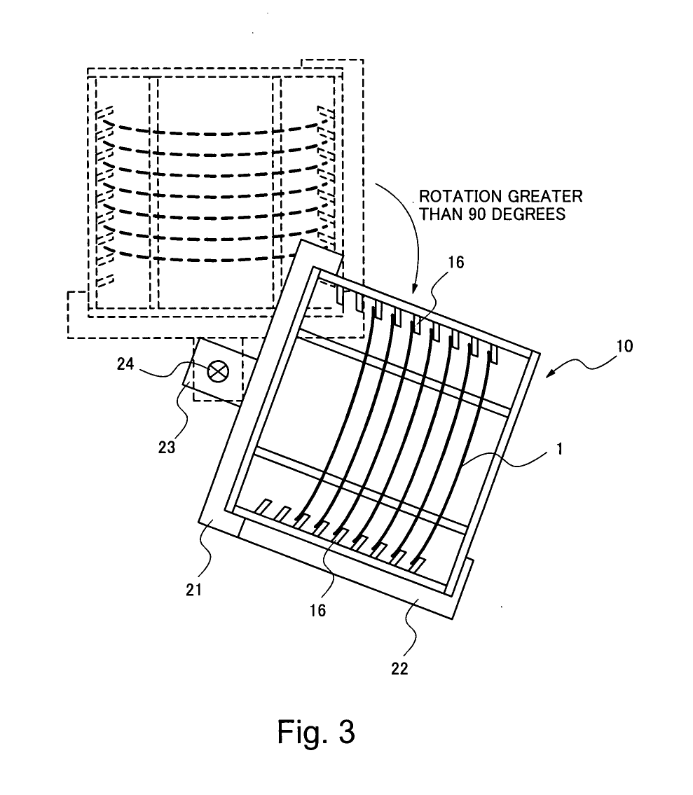

As shown in FIG. 3, the holding apparatus for a substrate cassette 10 of this embodiment rotates the support bases 21 and 22 together with cassette 10 around the rotary shaft 24 of the tilting device 23. In this rotation, the first support base 21 is rotated such that a left side portion of the cassette 10 is lifted upward at the start of the rotation. At the end of the rotation, the processed surfaces of the substrates 1 are rotated to over vertical position so that the processed surfaces face downward and thereby dust does not adhere to the top surfaces, i.e., the processed surfaces of the substrates.

Next, a storage method for a substrate cassette of this embodiment will be described with reference to drawings. The substrates 1 are stored in the cassette 10 would be delivered to a production line as in the conventional process. The storage method for a substrate cassette of this embodiment is characterized by storing the substrates 1 in the cassette 10, rotating these substrates 1 at the range beyond 90 degrees to the horizontal plane, holding it in this rotated state, and keeping.

First, the cassette 10 is put on the supporting bases 21 and 22 so that the cassette 10 is fixed to a holding apparatus 20. Next, the support bases 21 and 22 together with the cassette 10 are rotated around a rotary shaft 24 of a tilting device 23 over 90 degrees as shown in FIG. 3. As a result, all of the processed surfaces of the substrates are rotated form a horizontal position to an over vertical position. That is, one main surface where the pattern 2 shown in FIG. 9 was formed faces downward, so that dust does not adhere to the processed surfaces of the substrates.

When the substrates 1 are usually supplied from a storage apparatus, a cassette 10 is received by placing a pattern surface of the substrates 1 upward. In this embodiment, when the cassette 10 is held and kept or conveyed, the cassette 10 needs to be inclined such that a pattern surface of the substrates 1 faces to the bottom. Thus, in order to fix the cassette 10 on the supporting bases 21 and 22 firmly in the state that inclined the cassette 10, the frame parts 25 are set up to the first support base 21, and the frame part 26 is set up to the second support base 22. By cooperation of the first and second support bases 21 and 22, the first frame parts 25 and the second frame part 26, the cassette 10 is held firmly with them.

In order to hold the cassette 10 in storage mode, the rotary shaft 24 is locked so as not to rotate any more after rotating only the predetermined angle beyond 90 degrees. The rotary shaft 24 can be locked easily by using a conventional fixing means such as a pin and a screw attached to the rotary shaft 24.

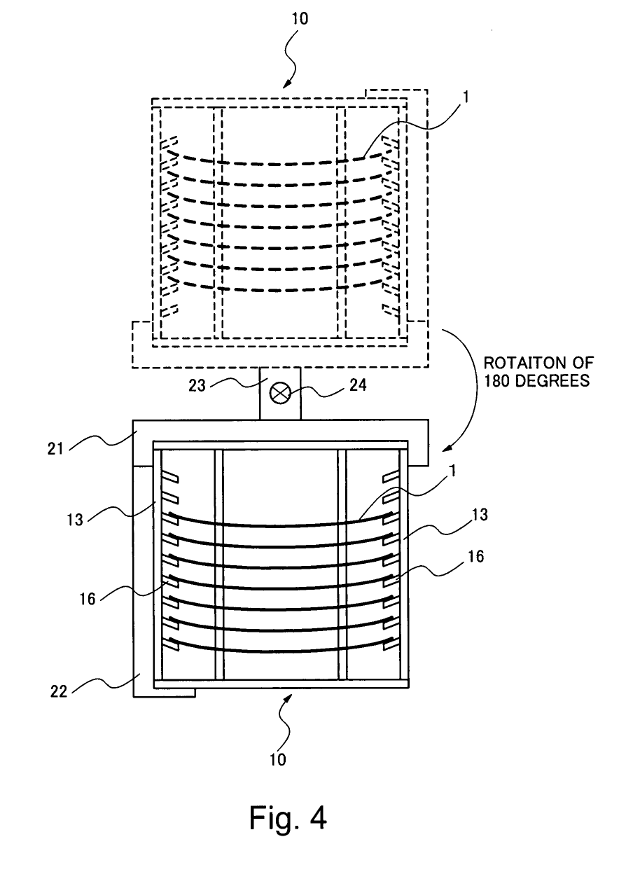

By further rotating the tilting device 23 around a rotary shaft 24, a tilting device 23 can reverse the support bases 21 and 22 of the cassette 10. In this case, by 180 degrees of rotation, as shown in FIG. 4, processed surfaces of the substrates 1 face to the bottom. In this state, the substrates 1 are held in the state that outer edge sections of processed surfaces of the substrates 1 are supported by the supporting plates 16 of the side plate 13. By installing driving equipment such as an actuator in the first support base 21, it is possible to rotate a cassette 10 and stop at arbitrary angles. The second support base 22 would mainly hold the cassette 10 after the rotation of the cassette 10. In this case, as shown in FIG. 3 or FIG. 4, even if the cassette 10 rotates beyond 90 degrees, the cassette 10 is supported by support bases 21 and 22 and the frame parts 25 and 26 and thus the cassette does not fall off.

Low rotating speed is desirable for the cassette 10 so as not produce a swing movement to the substrates 10. Further, when a storage period of the cassette 10 has ended, the tilting device 23 is rotated conversely, and the cassette 10 can be taken out by returning it in the initial state of FIG. 1.

A case when a substrate is kept using a holding apparatus 20 for a substrate cassette of this embodiment is considered. In the third related art, in order to keep a cassette though it was in the clean room, a large storing apparatus called a bay or a buffer was needed. It was necessary to introduce clean air in the clean room into a cassette to maintain the clean state.

In contrast, in the holding apparatus 20 for a substrate of this embodiment, because the cassette 10 rotates around the rotary shaft 24, only space for storing the cassette 10 is needed. When the substrates 1 are kept using the holding apparatus for a substrate of this embodiment, dust is not stuck on processed surface of the substrates 1, and the cassette 10 can be held by the holding apparatus 20. In this embodiment, the substrates 1 can be kept cleanly sufficiently only by keeping the holding apparatus 20 for a substrate in the clean room, and a large storing apparatus called a bay or a buffer is not needed any more, and the storage space can be made small consequently.

When substrates 1 is small and the storing number of the cassette 10 is small, and conveyance by a hand is possible, the tilting device 23 is rotated by hand, and only a storage mode should be performed and held as shown in FIG. 3 or FIG. 4. In that case, a driving means of the tilting device 23 is not required. Further, even if a cassette 10 was large, it would be possible to rotate and keep it before storing the substrates. It may be possible to put a cassette 10 in the support bases after rotating the holding apparatus.

In this embodiment, since the processed surface of the substrates 1 are kept to be faced downward, dust does not adhere to the processed surfaces of the substrates 1. Therefore, clean room is enough, and a storage apparatus such as the buffer as mentioned above becomes unnecessary.

As to operation of a holding apparatus of FIG. 1 the cassette 10 with the substrates is put on the support bases 21 and 22 as mentioned above. Loading of these substrates 1 may be done by hand or may be done by using a conveying robot as in the third related art. When the cassette 10 receives a signal of loading for the glass substrates, the tilting device 23 is driven and the cassette 10 is rotated by an actuator of rotary type. In this case, a sensor is installed in support bases 21 and 22, and an equipped signal of the substrates 1 may be received and when it is a stacker like the third related art, a stock signal may be detected by a sensor of a storage place.

When a storage period of the cassette 10 ends, operation of the actuator is released and the cassette 10 is returned to the original state and the cassette 10 should be taken out by reverse operation at the time of loading.

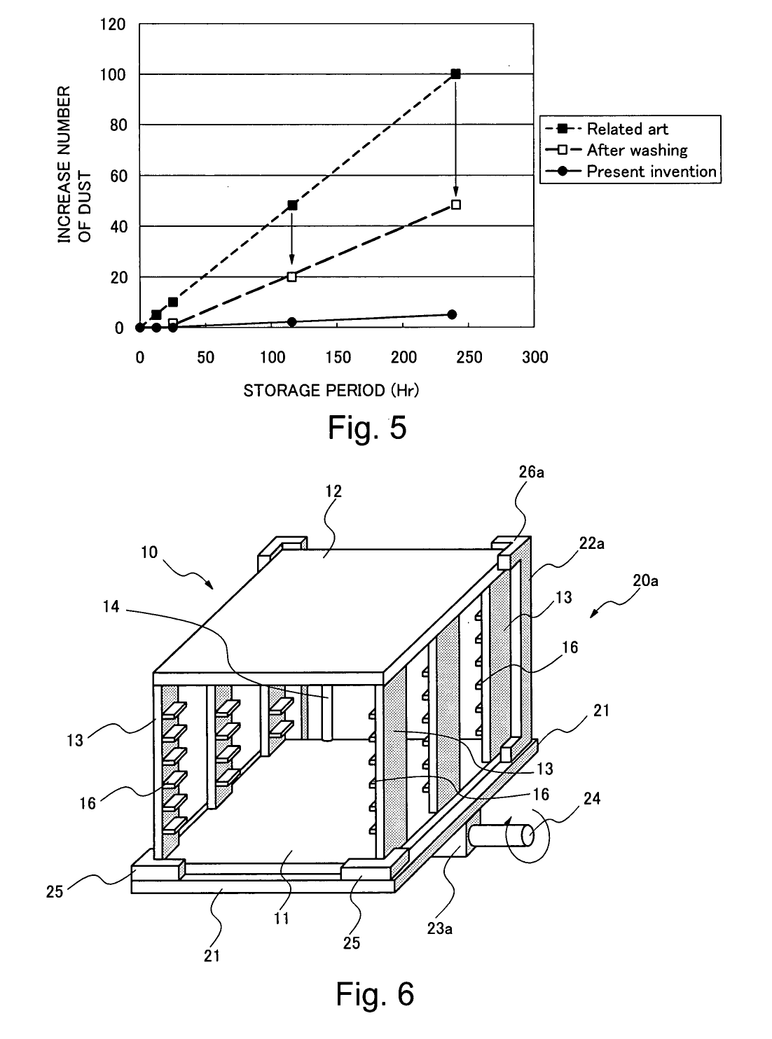

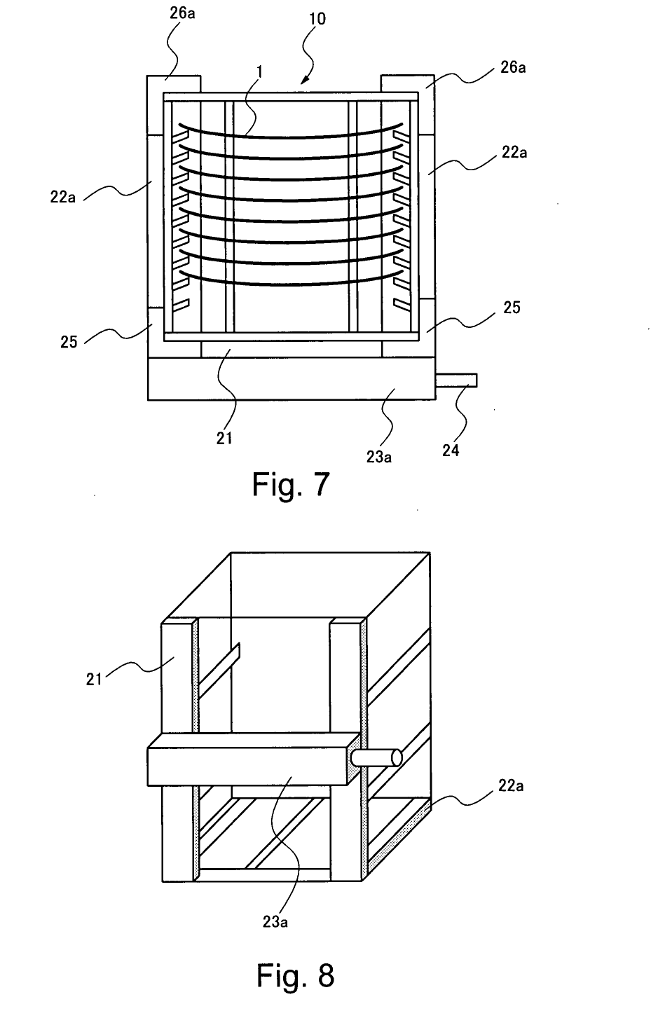

FIG. 5 is a graph showing a result which measured the number of the dust adhered to the processed surface of the glass substrates during storage period. In case of the related art, the number of the dust adhered to the surface of the substrate was one hundred pieces per 250 hours as shown by a dotted line with black quadrangles. Even after washing this glass substrate, the number of the dust is left nearly fifty pieces per 250 hours. In contrast, according to this embodiment, number of the dust is ten or less pieces per 250 hours. It was revealed that the number of the adhered dust decreased remarkably. In this embodiment, thus, by keeping in the state that rotated the glass substrate beyond 90 degrees, it was confirmed that the dust which adheres to the processed surface of substrates can be made approximately zero.

Next, a holding apparatus and a storage method for a substrate according to the second exemplary embodiment will be described with reference to drawings. As shown in FIG. 6, a holding apparatus 20a for a substrate cassette includes a first support base 21, second support bases 22a, a tilting device 23a with a rotary shaft 24, a first frame parts 25 and a second frame parts 26a. The first support base 21 supports a floor plate 11 of a cassette 10 for storing glass substrates. The second support base 22a supports a rear side of the cassette 10. The tilting device 23a is provided in the base center of the first support base 21 and rotates the support bases 21 and 22a around a rotary shaft 24. The rotary shaft 24 is arranged to have a horizontal axis extending to the substantially perpendicular direction of the insertion direction or loading direction of the substrates 1 to the cassette 10. Frame parts 25 and 26a are provided on four corners of each of support bases 21 and 22a to support the cassette 10. The cassette 10 is fixed and held in a space surrounded by the first support base 21, the second support base 22a, the frame parts 25 and the frame parts 26a. In this embodiment, the holding apparatus 20a for a substrate cassette which rotates a glass substrate toward the rear side of the cassette 10 as shown in FIG. 6, not a transverse direction like FIG. 1. In other words, end of the first support base 21 close to the loading/unloading aperture of the cassette 10 is lifted up at the beginning of the rotation. In this embodiment, although the cassette 10 is held by the support bases 21 and 22a, the support bases 22a are set up to a rear side of the first support base 21. Frame parts 25 and 26a have a shape of letter “L” are provided on the four corners to support the cassette 10.

In the holding apparatus 20a for a substrate cassette of this embodiment, the support bases 21 and 22a with cassette 10 for substrates can be rotated around the rotary shaft 24 of the tilting device 23a in the state that the cassette 10 was set to the support bases 21 and 22a. As a result, the first support base 21 can be rotated in the rear direction of the cassette 10. In other words, it is a kind of rotation caused by pulling down the side of the stopper 14 at a rear side of the cassette 10.

The storage method of this embodiment is characterized by storing the substrates 11 in the cassette 10, rotating these substrates 1 at the range beyond 90 degrees to the horizontal plane, holding it in this rotated state, and keeping.

First, the cassette 10 in which the substrates 1 was stored is set to the supporting bases 21 and 22a, and the cassette 10 is fixed on a holding apparatus 20a. Next, the support bases 21 and 22a with the cassette 10 are rotated around a rotary shaft 24. In this rotation, as shown in FIG. 6, it is rotated around the rotary shaft 24 of the tilting device 23a centering on a central part of the first support base 21. It is desirable to set an angle of rotation of the cassette 10 for these substrates that the surface of the substrates 1 faces downward by rotating over 90 degrees so that dust does not adhere to the processed surfaces of the substrate surface as in the case of the first embodiment. That is, it is desirable to hold and keep it in the state that processed surfaces of the substrates face downward. When the support bases 21 and 22a are rotated to the rear side, the substrates 1 are supported by a stopper 14, and the cassette 10 is mainly held by the second base support 22.

As to the direction of rotation of the cassette 10, it is desirable to rotate such that rotational axis is parallel to the long side of the substrates 1. This is because, the movements of the substrates 1 becomes stable. When the cassette 10 is rotated, in order to make it a rotation around axis parallel to the long side of the substrates 1, the structure of the cassette 10 and the mounting direction of the cassette 10 to the holding apparatus 20a should be set appropriately.

When the holding apparatus and the storage method for a substrate cassette according to this embodiment were applied, the number of the adhered dust during storage mode decreased remarkable like the first exemplary embodiment.

A storage method for a substrate cassette according to an exemplary embodiment of the present invention includes a step of placing and keeping the holding apparatus for a substrate mentioned above in a clean room directly.

The present invention can be applied to a storage method of a holding apparatus for a substrate for display panels and a substrate as mentioned above. Generally it is applicable not only to a glass substrate but the device using the cassette for substrates which stores plate-like substrates, such as a plastic board, a ceramic substrate, or a semiconductor wafer.

While this invention has been described in connection with certain preferred embodiments, it is to be understood that the subject matter encompassed by way of this invention is not to be limited to those specific embodiments. On the contrary, it is intended for the subject matter of the invention to include all alternative, modification and equivalents as can be included within the spirit and scope of the following claims.

What is claimed is:

1. A holding apparatus for a substrate cassette, comprising:
a cassette for storing a plurality of substrates;
a support base for holding the cassette; and
a tilting device fixed to the support base for allowing the support base to rotate about a horizontal axis from a horizontal position, wherein top surfaces of the substrates are arranged upwardly, to an over vertical position, wherein the top surfaces of the substrates are arranged downwardly, by rotating the support base over 90 degrees.

2. The holding apparatus for a substrate cassette according to claim 1, wherein the tilting device is provided with a rotary shaft elongating to the horizontal axis.

3. The holding apparatus for a substrate cassette according to claim 2, wherein the cassette comprises a floor plate, a top plate and side plates extending between the floor plate and the top plate, and the side plates are provided with supporting teeth protruded therefrom to support the substrates inserted through an opening revealing the teeth.

4. The holding apparatus for a substrate cassette according to claim 2, wherein the tilting device rotates the support base approximately 180 degrees around the rotary shaft.

5. The holding apparatus for a substrate cassette according to claim 1, wherein the support base holds the cassette by supporting a bottom and a side of the cassette.

6. The holding apparatus for a substrate cassette according to claim 5, wherein the support base includes a first support base supporting a bottom of the cassette, and a second support base supporting a side of the cassette.

7. The holding apparatus for a substrate cassette according to claim 5, wherein the rotary shaft is substantially parallel to an insertion direction of the substrates to the cassette.

8. The holding apparatus for a substrate cassette according to claim 1, wherein the support base holds the cassette by supporting a bottom and a back of the cassette.

9. The holding apparatus for a substrate cassette according to claim 8, wherein the support base includes a first support base supporting a bottom of the cassette, and a second support base supporting a back of the cassette.

10. The holding apparatus for a substrate cassette according to claim 5, wherein the rotary shaft is substantially perpendicular to an insertion direction of the substrates to the cassette.

11. A storage method for a substrate cassette, comprising the steps of:
storing substrates in a cassette for substrates almost horizontally;
fixing the cassette on a support base; and
rotating the support base around a rotary shaft until the substrate will rotate 90 degrees or more.

12. The storage method for a substrate cassette according to claim 11, wherein the cassette forms a box structure with a floor plate, a top plate and a plurality of supports, and stores a plurality of the substrates between the plurality of supports.

13. The storage method for a substrate cassette according to claim 12, wherein the tilting device can rotate the support base to approximately 180 degree around the rotary shaft.

14. The storage method for a substrate cassette according to claim 11, wherein the support base holds the cassette by supporting a bottom and a side of the cassette.

15. The storage method for a substrate cassette according to claim 14, wherein the tilting device is fixable where the support base is rotated in a direction of a side of the cassette.

16. The storage method for a substrate cassette according to claim 11, wherein the support base holds the cassette by supporting a bottom and a back of the cassette.

17. The storage method for a substrate cassette according to claim 16, wherein the tilting device is fixable where the support base is rotated in a direction of a back of the cassette.
